(19) United States
(12) Patent Application Publication
(10) Pub. No.: US 2004/0212069 A1
(43) Pub. Date: Oct. 28, 2004

(54) Multi-chips stacked package

(75) Inventors: Yu-Wen Chen, Kaohsiung (TW); Meng-Jen Wang, Pingtung City (TW); Chi-Hao Chiu, Pingtung City (TW)

Correspondence Address: BACON & THOMAS, PLLC, 625 SLATERS LANE, FOURTH FLOOR, ALEXANDRIA, VA, 22314

(73) Assignee: Advanced Semiconductor Engineering, Inc., Kaoshiung (TW)

(21) Appl. No.: 10/820,854

(22) Filed: Apr. 9, 2004

(30) Foreign Application Priority Data
Apr. 25, 2003 (TW) 092109654

(51) Int. Cl. H01L 23/02

(52) U.S. Cl. 257/686; 257/738; 257/777

(57) ABSTRACT

A multi-chips stacked package comprises a substrate, an upper chip, a lower chip, a dam, a heat spreader, an underfill, a plurality of first electrically conductive bumps and a plurality of second electrically conductive bumps. The upper chip is flip-chip bonded to the upper surface of the substrate and the second chip is accommodated in the opening and flip-chip bonded to the upper chip. Furthermore, the dam is disposed on the substrate and supports the heat spreader so as to fix the heat spreader to the back surface of the first chip. In addition, the underfill is filled into the space which is enclosed by the dam, the upper surface of the substrate and the heat spreader. In such a manner, at least the upper chip, the lower chip, the first and second electrically conductive bumps and a portion of the substrate are covered by the underfill. Thus, the underfill is connected to the dam, the heat spreader and the substrate simultaneously, so the reinforced structure including the heat spreader, the underfill and the dam can restrain the thermal deformation of the substrate and the upper chip and prevent the first electrically conductive bumps connecting the upper chip and the substrate from being damaged.

### BACKGROUND OF THE INVENTION

1. Field of Invention

This invention relates to a multi-chips stacked package having a heat spreader and a dam therein. More particularly, the present invention is related to a multi-chips stacked package with a dam that is utilized for enclosing the underfill which covers the upper surface of the substrate and encloses an upper chip and a lower chip so as to prevent the underfill from bleeding and have the underfill connected to the substrate and the heat spreader in a suitable manner. Thus, the electrically conductive bumps connecting the substrate and the upper chip will be prevented from being damaged due to lower the stress at the electrically conductive bumps.

2. Related Art

As we know, in the semiconductor industries, the manufacture of semiconductors mainly comprises the manufacture of wafers and the assembly of integrated circuits devices. Therein, the integrated circuits (ICs) devices are completely formed by the processes of forming integrated circuits devices on the semiconductor wafers, sawing the wafers into individual integrated circuits devices, placing the individual integrated circuits devices on the substrates, electrically connecting the integrated circuits devices to the substrates and encapsulating the integrated circuits devices and substrates to form a plurality of assembly packages. Due to the encapsulation covering the integrated circuits devices, the integrated circuits devices are able to be protected from the damp entering. In addition, the assembly packages may further provide external terminals for connecting to printed circuit board (PCB).

However, recently, integrated circuits packaging technology is becoming a limiting factor for the development in packaging integrated circuits devices of higher performance. Semiconductor package designers are struggling to keep pace with the increase in pin count, size limitations, low profile, and other evolving requirements for packaging and mounting integrated circuits.

Due to the assembly package in miniature and the integrated circuits operation in high frequency, MCM (multi-chips module) packages are commonly used in said assembly packages and electronic devices. Usually, said MCM package mainly comprises at least two chips encapsulated therein, for example a processor unit, a memory unit and related logic units, so as to upgrade the electrical performance of said assembly package. In addition, the electrical paths between the chips in said MCM package are short so as to reduce the signal delay and save the reading and writing time.

Per the above-mentioned, a multi-chips stacked package is provided, as shown in FIG. 1, as a standard and common design. Referring to FIG. 1, it is characterized that an upper chip 110 is flipped over and disposed above an opening 122 passing through the upper surface 124 and the lower surface 126 of the substrate 120 and a lower chip 130 is accommodated in the opening 122 and electrically connected to the upper chip 110 through electrically conductive bumps 170. Generally speaking, the upper chip 110 and the lower chip 130 are a memory chip and a logic chip respectively. In such a manner, the electrical signals are able to be integrated in the package and then are transmitted to external devices through solder balls 128 attached to the lower surface 126 of the substrate 120. Accordingly, the size of said multi-chips stacked package is reduced and the transmission path of the electrical signals are shortened. Namely, the signal delay is reduced and the electrical performance of said multi-chips stacked package is upgraded.

As mentioned above and per the conventional invention as shown in FIG. 1, the upper chip 110 is electrically connected to the substrate 120 through electrically conductive bumps 170. Generally, the organic substrate, for example Bismaleimide-Triazine (BT), is taken as the substrate 120 to carry the upper chip 110 wherein the coefficient of thermal expansion of the substrate120 is about 16*10⁻⁶ ppm/° C. and the coefficient of thermal expansion of the upper chip 110 is about 4*10⁻⁶ ppm/° C. Accordingly, the coefficient of thermal expansion of the upper chip 110 is much smaller than that of the substrate 120 and the electrically conductive bumps 170 connecting the upper chip 110 and the substrate 120 are usually damaged due to the CTE mismatch of the substrate 120 with the upper chip 110. Notwithstanding, there is an underfill 160 interposed between the upper chip 110 and the substrate 120 and filled into the space between the upper chip 110 and the substrate 120 to lower the stress at the electrically conductive bumps 170, the bumps 170 are still damaged due to the much difference of the coefficient of thermal expansion of the substrate 120 from that of the upper chip 110.

Therefore, providing another multi-chips stacked package to solve the mentioned-above disadvantages is the most important task in this invention.

### SUMMARY OF THE INVENTION

In view of the above-mentioned problems, an objective of this invention is to provide a multi-chips stacked package which is characterized in that the electrically conductive bumps provided in the multi-chips stacked package is able to be prevented from being damaged due to a reinforced structure made of the underfill, the heat spreader and the dam.

To achieve the above-mentioned objective, a multi-chips stacked package is provided, wherein the multi-chips stacked package mainly comprises a substrate having an opening, an upper chip, a lower chip, a heat spreader, a dam, a plurality of electrically conductive bumps and an underfill. Therein, the upper chip is flipped over and disposed above the opening, and the active surface of the upper chip is attached to the upper surface of the substrate through the electrically conductive bumps; the lower chip is accommodated in the opening and connected to the upper chip by another electrically conductive bumps; and the heat spreader is attached to the back surface of the upper chip. Moreover, the dam is disposed on the substrate and below the heat spreader, and connected to the heat spreader; and the underfill is filled in a space enclosed by the dam, the upper surface of the substrate and the heat spreader so as to have the underfill connected to the heat spreader, the dam and the substrate in a suitable manner. Accordingly, a reinforced structure, is formed by the heat spreader, the underfill and the dam, lowers the stress at the electrically conductive bumps connecting the upper chip and the substrate and to prevent the electrically conductive bumps from being damaged.

In summary, this invention is related to a multi-chips stacked package utilizing a dam for enclosing the underfill which covers the upper surface of the substrate and encloses the upper chip and the lower chip so as to prevent the underfill from bleeding and have the underfill connected to the substrate and the heat spreader in a suitable manner. Thus, the stress at the electrically conductive bumps interposed between the upper chip and the substrate will be lowered. In such a manner, the electrically conductive bumps connecting the substrate and the upper chip will be prevented from being damaged. As mentioned above, the underfill is connected to the heat spreader, the dam and the substrate so as to restrain the warpage of the substrate and the deformation of the upper chip. Moreover, when the coefficient of the thermal expansion of the heat spreader be substantially the same as the substrate is provided, for example a dummy chip, the substrate and the heat spreader with higher stiffness and much rigidity will be regarded as covers to have the upper chip to be interposed between the heat spreader and the substrate to form a sandwich beam structure. Accordingly, the underfill is regarded as a core layer and able to absorb a lot of stress energy and the shear stress at the electrically conductive bumps connecting the substrate and the upper chip. Thus, the substrate is prevented from being warped so that the reliability of the multi-chips stacked package will be upgraded. Moreover, the heat spreader is mounted on the back surface of the upper chip so that the thermal performance of the multi-chips stacked package will be enhanced.

### BRIEF DESCRIPTION OF THE DRAWINGS

The invention will become more fully understood from the detailed description given herein below illustrations only, and thus are not limitative of the present invention, and wherein:

FIG. 1 is a cross-sectional view of the conventional multi-chips stacked package;

FIG. 2 is a cross-sectional view of a multi-chips stacked package according to the preferred embodiment;

FIG. 3 is a cross-sectional view along line AA′ of the multi-chips stacked package shown in FIG. 2; and

FIG. 4 is a cross-sectional view of a multi-chips stacked package according to another preferred embodiment.

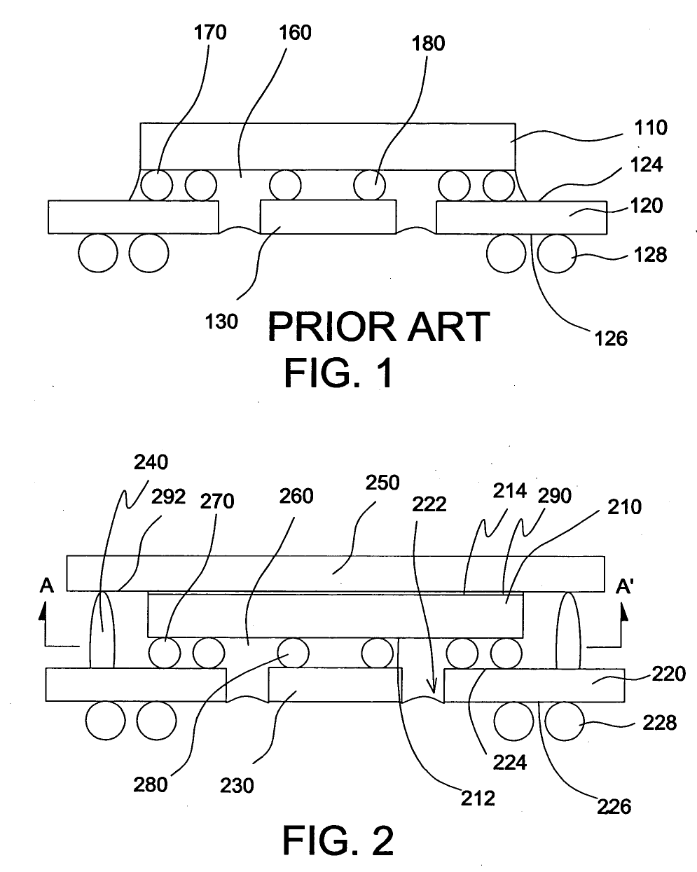

### DETAILED DESCRIPTION OF THE INVENTION

The multi-chips stacked package according to the preferred embodiments of this invention will be described herein below with reference to the accompanying drawings, wherein the same reference numbers refer to the same elements.

In accordance with a preferred embodiment as shown in FIG. 2, there is provided a multi-chips stacked package. Referring to FIG. 2, the multi-chips stacked package mainly comprises an upper chip 210, a substrate 220 having an opening 222, a lower chip 230, a dam 240, a heat spreader 250, an underfill 260, a plurality of first electrically conductive bumps 270, and a plurality of second electrically conductive bumps 280. Therein, the substrate 220 further has an upper surface 224 and a lower surface 226, and the opening 222 passes through the upper surface 224 and the lower surface 226. Besides, the upper chip 210 is flipped over and attached on the upper surface 224 of the substrate 220 via a plurality of first electrically conductive bumps 270 so as to cover the opening 222 of the substrate 220. Moreover, the lower chip 230 is accommodated in the opening 222 and attached to the upper chip 220 via a plurality of second electrically conductive bumps 280.

Furthermore, the heat spreader 250 is attached to the back surface 214 of the upper chip 210 through an adhesive layer 290 and is mounted on the dam 240 that is disposed between the substrate 220 and the lower surface 252 of the heat spreader 250. Therein, the adhesive layer 290 may be a thermally conductive epoxy so as to enhance thermal performance of the multi-chips stacked package. In addition, the dam 240 surrounds the upper chip 210. In such a manner, the dam 240, the heat spreader 250 and the upper surface 224 of the substrate 220 enclose a space 300 for filling with said underfill 260. Thus, the upper chip 210, the lower chip 230, the first electrically conductive bumps 270 and the second electrically conductive bumps 280 are enclosed by the underfill 260, and a portion of the substrate 220 is covered by said underfill 260 so as to have the underfill 260 connected to the heat spreader 250, the dam 240 and the upper surface 224 of the substrate 220. Accordingly, a reinforced structure comprising the underfill 260, the dam 240 and the heat spreader 250 is formed to restrain the deformation of the upper chip 210 and the warpage of the substrate 220 and to prevent the first electrically conductive bumps 270 from being damaged due to CTE mismatch of the substrate 220 with the upper chip 210. Moreover, a plurality of solder balls 228 are provide on the lower surface 226 of the substrate 220 so as to electrically connect to external electronic devices. It should be noted that the underfill may be replaced with another encapsulation, such as epoxy and plastic polymer.

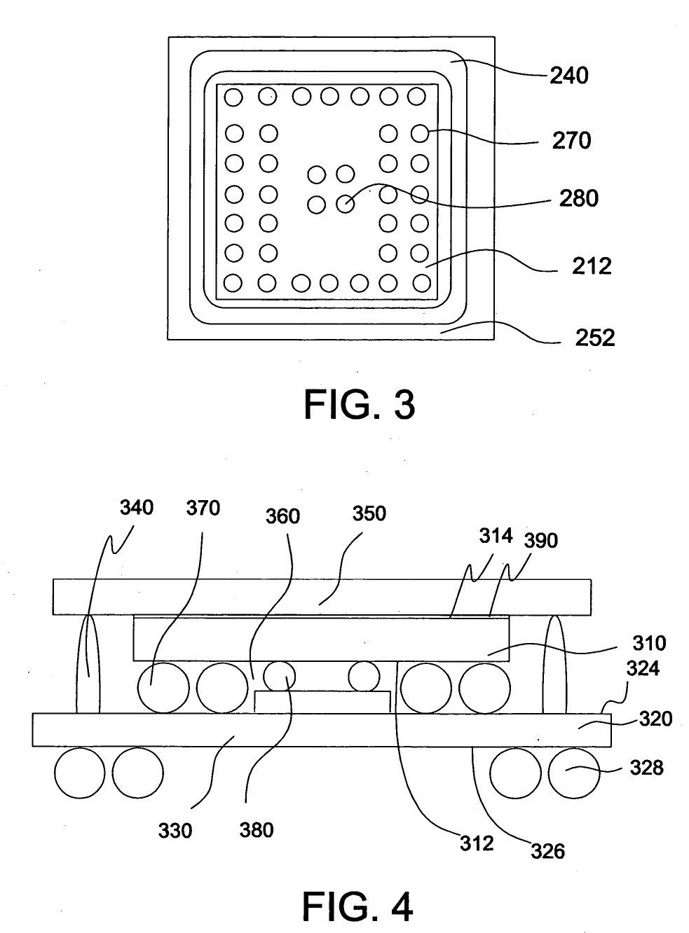

As mentioned above, the dam 240 may be an adhesive body made of an epoxy or a thermally conductive epoxy, and is disposed on the upper surface 222 of the substrate 220 by dispensing method. Furthermore, the dam 240 surrounds the periphery of the chip 210, and is shaped into a ring as shown in FIG. 3 or four bars located at the four sides (not shown). Namely, the dam 240 encloses the upper chip 210 and prevents the underfill 260 from bleeding.

As mentioned above, when the thickness or the size of the upper chip 210 is larger than usual one, the heat spreader 250 can be made of a material with a coefficient of thermal expansion similar with the substrate 220. On the contrast, when the thickness or the size of the upper chip 210 is smaller than usual one, the heat spreader 250 can be made of a material with a coefficient of thermal expansion similar with the chip. For example, a dummy chip is taken as a heat spreader. Because the coefficient of thermal expansion of the heat spreader 250 is ranged between the chip and the substrate and a reinforced structure is formed by the underfill 260, the dam 240 and the heat spreader 250, the warpage of the substrate 220 and the deformation of the upper chip 210 will be restrained to avoid the first electrically conductive bumps 270 connecting the upper chip 210 and the substrate 220 being damaged. It should be noted that the heat spreader 250 is a flat plate and the material of the heat spreader is made of copper or aluminum so that the thermal performance of the multi-chips stacked package will be enhanced. When the package is taken for communication and wire-less module application, a lead frame as lead-less lead frame, will replace the substrate.

Moreover, when the substrate 320 has no opening therein, the lower chip 230 will be placed above the upper surface 324 of the substrate 320 as shown in FIG. 4 which is taken as a second preferred embodiment. Accordingly, the height of the first electrically conductive bump 370 connecting the upper chip 310 to the substrate 320 is larger than that of the electrically conductive bump 380 connecting the lower chip 330 to the upper chip 310.

Although the invention has been described in considerable detail with reference to certain preferred embodiments, it will be appreciated and understood that various changes and modifications may be made without departing from the spirit and scope of the invention as defined in the appended claims.

What is claimed is:

1. A multi-chips stacked package, comprising:
a substrate having an upper surface, a lower surface and an opening passing through the upper surface and the lower surface;
an upper chip having a first active surface and a first back surface wherein the upper chip is flipped over and attached to the upper surface of the substrate via a plurality of first electrically conductive bumps;
a lower chip accommodated in the opening and electrically connected to the first active surface of the upper chip through a plurality of second electrically conductive bumps;
a dam disposed on the upper surface of the substrate; and
a heat spreader attached to the first back surface of the upper chip and attached to the dam.

2. The multi-chips stacked package of claim 1, further comprising an adhesive layer interposed between the heat spreader and the first back surface of the upper chip.

3. The multi-chips stacked package of claim 2, wherein the adhesive layer is a thermally conductive epoxy.

4. The multi-chips stacked package of claim 1, wherein the dam is disposed at the periphery of the upper surface of the substrate and surrounds the upper chip.

5. The multi-chips stacked package of claim 4, wherein the dam is ring-like.

6. The multi-chips stacked package of claim 1, further comprising an encapsulation filled in a space enclosed by the heat spreader, the upper surface of the substrate and the dam.

7. The multi-chips stacked package of claim 6, wherein the encapsulation comprises an underfill.

8. The multi-chips stacked package of claim 7, wherein the underfill encloses the upper chip, the lower chip, the first electrically conductive bumps and the second electrically conductive bumps, and covers the upper surface of the substrate.

9. The multi-chips stacked package of claim 7, wherein the underfill is connected to the upper surface of the substrate, the heat spreader and the dam.

10. The multi-chips stacked package of claim 1, wherein a material of the heat spreader comprises copper.

11. The multi-chips stacked package of claim 1, wherein a material of the heat spreader comprises aluminum.

12. The multi-chips stacked package of claim 1, wherein the heat spreader is a flat plate.

13. The multi-chips stacked package of claim 1, further comprising a plurality of solder balls formed on the lower surface of the substrate.

14. The multi-chips stacked package of claim 1, wherein the dam is an adhesive body.

15. The multi-chips stacked package of claim 1, wherein a material of the dam comprises epoxy.

16. The multi-chips stacked package of claim 15, wherein the material of the dam is selected from thermally conductive epoxy.

17. The multi-chips stacked package of claim 1, wherein the dam is formed in a bar-like shape.

18. The multi-chips stacked package of claim 8, wherein the lower chip has a second back surface exposing out of the underfill.

19. The multi-chips stacked package of claim 1, wherein the heat spreader is a flat plate.

20. The multi-chips stacked package of claim 1, further comprising a plurality of solder balls formed on the lower surface of the substrate.

21. The multi-chips stacked package of claim 1, wherein the upper chip is larger than the lower chip in size.

22. A multi-chips stacked package, comprising:
a substrate having an upper surface and a lower surface;
an upper chip having a first active surface and a first back surface wherein the upper chip is flipped over and attached to the upper surface of the substrate via a plurality of first electrically conductive bumps;
a lower chip disposed above the upper surface of the substrate and electrically connected to the first active surface of the upper chip through a plurality of second electrically conductive bumps;
a dam disposed at the periphery of the upper surface of the substrate; and
a heat spreader attached to the first back surface of the upper chip and attached to the dam.
an underfill enclosing the upper chip, the lower chip, the first electrically conductive bumps and the second electrically conductive bumps, and covering the upper surface of the substrate.

23. The multi-chips stacked package of claim 22, wherein the first electrically conductive bump is larger than the second electrically conductive bump in height.
